(19) United States
(12) Patent Application Publication
(10) Pub. No.: US 2025/0187031 A1
(43) Pub. Date: Jun. 12, 2025

(54) FLUID SUPPLY DEVICE

(71) Applicant: EBARA CORPORATION, Tokyo (JP)

(72) Inventor: SATOSHI AO, Tokyo (JP)

(73) Assignee: EBARA CORPORATION, Tokyo (JP)

(21) Appl. No.: 18/970,814

(22) Filed: Dec. 5, 2024

(30) Foreign Application Priority Data
Dec. 8, 2023 (JP) 2023-207603

(51) Int. Cl. B05B 12/12; H01L 21/67

(52) U.S. Cl. CPC B05B 12/124; H01L 21/67017

(57) ABSTRACT

Provided is a fluid supply device. The fluid supply device includes: a first nozzle that supplies a first fluid toward an object; a light sensor that includes a light-emitting part that emits light for detection, and a light-receiving part that receives the light; a first light-blocking member capable of being positioned in a first non-light-blocking position that does not block light and a first light-blocking position that blocks light; and a sensing part that detects displacement of the first nozzle based on a light reception amount of the light-receiving part. The first light-blocking member is capable of switching between the first light-blocking position and the first non-light-blocking position by displacing in conjunction with the displacement of the first nozzle.

### CROSS-REFERENCE TO RELATED APPLICATION

This application claims the priority benefits of Japanese application no. 2023-207603, filed on Dec. 8, 2023. The entirety of the above-mentioned patent application is hereby incorporated by reference herein and made a part of this specification.

### BACKGROUND

### Technical Field

The disclosure relates to a fluid supply device.

### Related Art

A supply device is used to supply fluid toward an object. The supply device includes, for example, a nozzle for supplying fluid (e.g. chemical liquid, rinse liquid, etc.) to a substrate such as a semiconductor wafer, etc. (see, for example, Patent Document 1).

### CITATION LIST

### Patent Document

[Patent Document 1] Japanese Patent Application Laid-Open Publication No. 2002-217159

In the device, it was not easy to accurately determine the position of the nozzle. If the position of the nozzle is inaccurate, it could become difficult to supply fluid (chemical liquid, rinse liquid, etc.) to the correct position relative to the object. Therefore, there has been a demand to accurately detect any misalignment that occurred in the position of the nozzle.

The disclosure aims to provide a fluid supply device capable of accurately detecting misalignment in the position of the nozzle.

### SUMMARY

According to a first aspect of the disclosure, a fluid supply device includes a first nozzle that supplies a first fluid toward an object; a light sensor that includes a light-emitting part that emits light for detection, and a light-receiving part that receives the light; a first light-blocking member capable of being be positioned in a first non-light-blocking position that does not block the light and a first light-blocking position that blocks the light; and a sensing part that detects displacement of the first nozzle based on a light reception amount of the light-receiving part. The first light-blocking member is capable of switching between the first light-blocking position and the first non-light-blocking position by displacing in conjunction with the displacement of the first nozzle.

### BRIEF DESCRIPTION OF THE DRAWINGS

FIG. 1 is a configuration diagram of a substrate processing device including a fluid supply device according to the first embodiment.

FIG. 2 is a perspective diagram of a part of the fluid supply device according to the first embodiment.

FIG. 3 is a perspective diagram of a part of the fluid supply device according to the first embodiment.

FIG. 4 is a cross-sectional diagram of a nozzle of the fluid supply device according to the first embodiment.

FIG. 5 is a plan view of a part of the fluid supply device according to the first embodiment.

FIG. 6 is an explanatory diagram showing the operation of the fluid supply device according to the first embodiment.

FIG. 7 is an explanatory diagram showing the operation of the fluid supply device according to the first embodiment.

FIG. 8 is an explanatory diagram showing the operation of the fluid supply device according to the first embodiment.

FIG. 9 is a schematic diagram showing a modification example of the first light-blocking member and the second light-blocking member.

FIG. 10 is a perspective diagram of a part of the fluid supply device according to the second embodiment.

### DESCRIPTION OF THE EMBODIMENTS

The following describes the fluid supply device of the disclosure with reference to the drawings.

### Substrate Processing Device

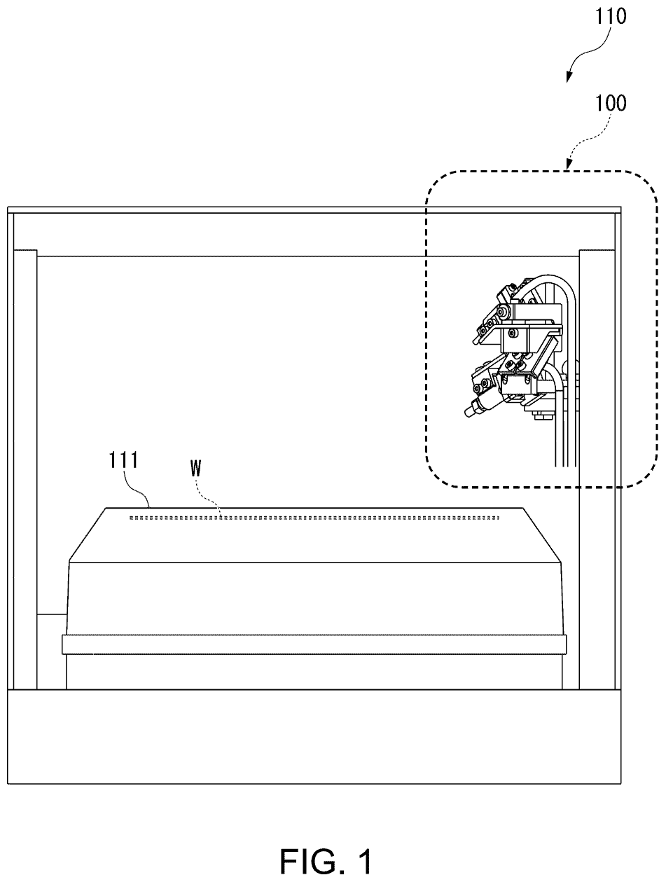

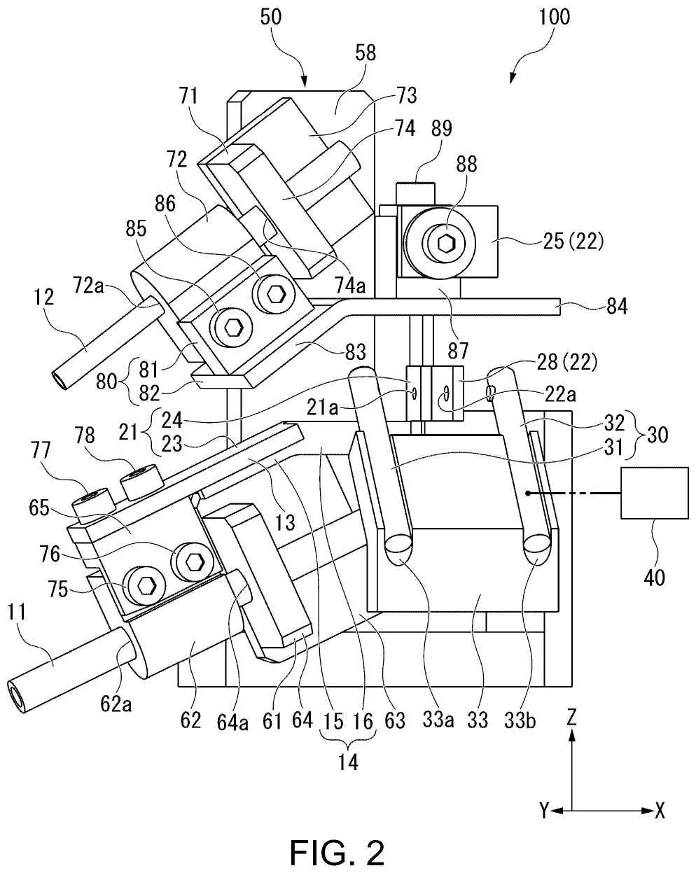

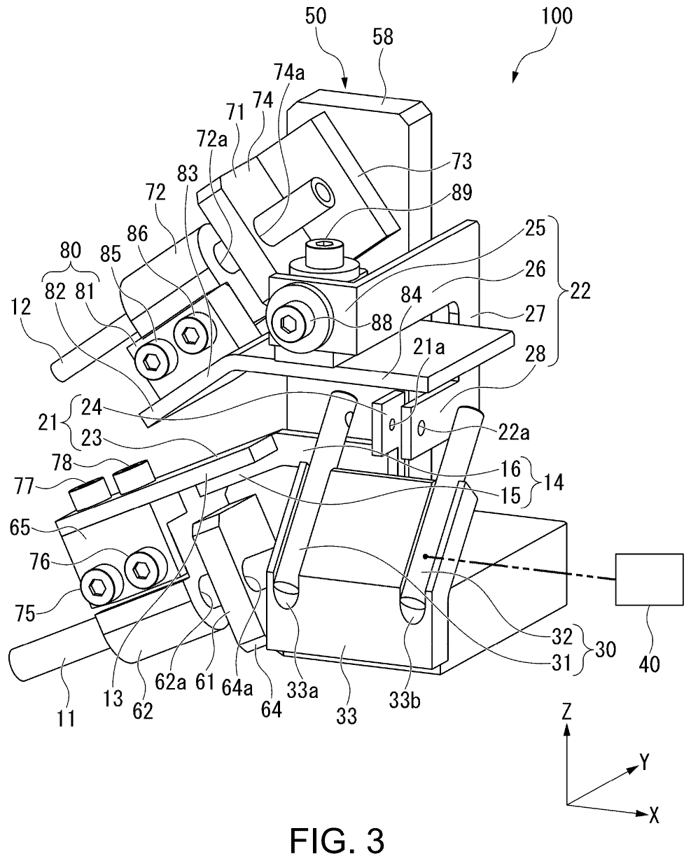

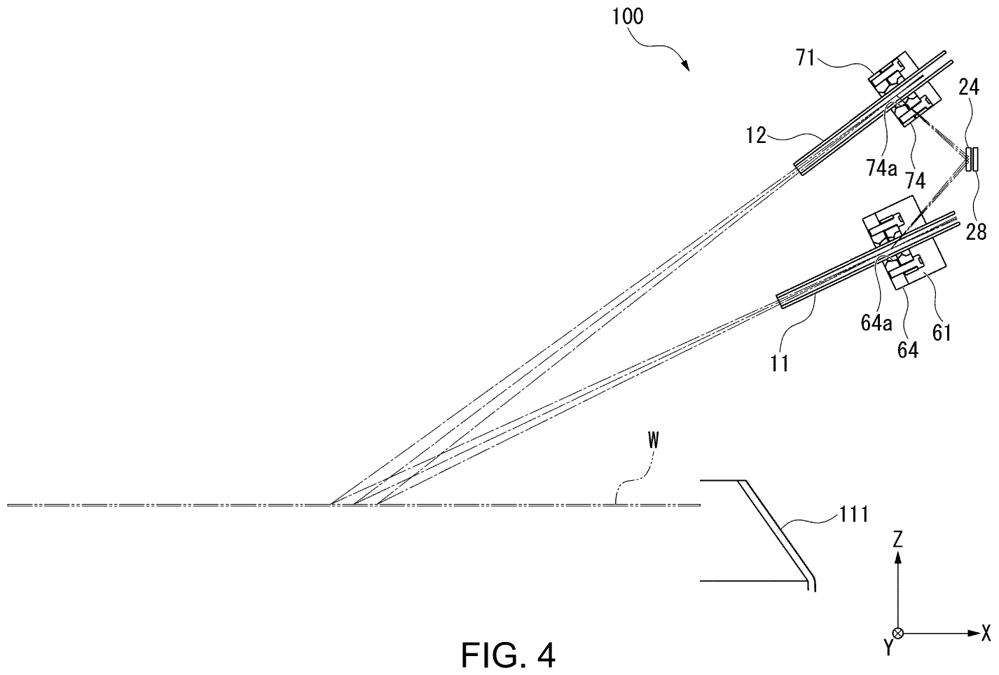

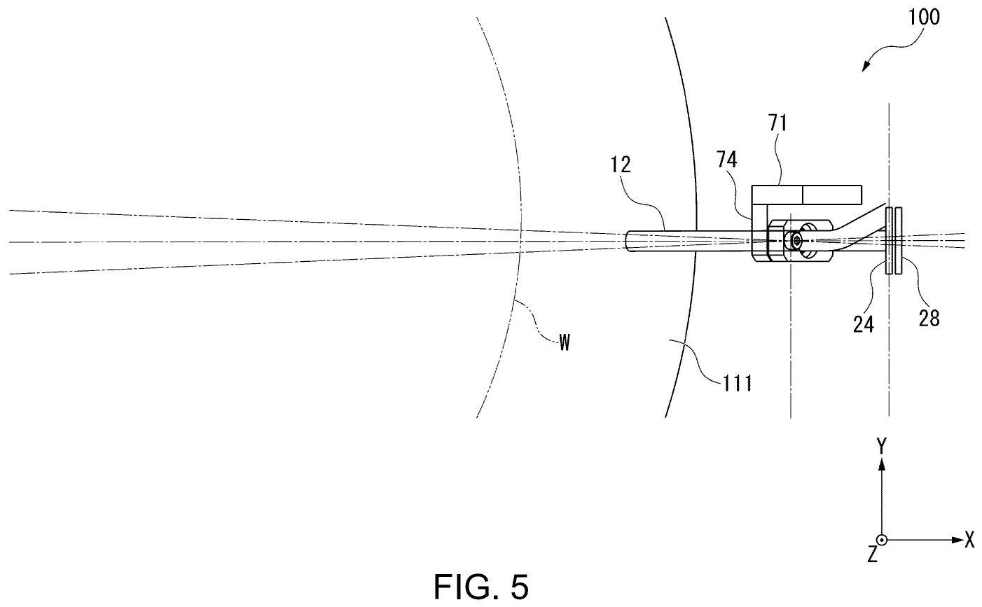

FIG. 1 is a configuration diagram of a substrate processing device 110 including a fluid supply device 100 according to the first embodiment. FIG. 2 is a perspective diagram of a part of the fluid supply device 100. FIG. 3 is a perspective diagram of a part of the fluid supply device 100. FIG. 4 is a cross-sectional diagram of a first nozzle 11 and a second nozzle 12. FIG. 5 is a plan view of a part of the fluid supply device 100.

As shown in FIG. 1, the substrate processing device 110, for example, cleans the surface of a substrate W while rotating the substrate W around the central axis of the substrate W in the presence of a cleaning liquid. The substrate W may be, for example, semiconductor wafers, etc. The substrate processing device 110 is, for example, a substrate cleaning device. The substrate W is an example of the object.

The substrate processing device 110 includes the fluid supply device 100 and a substrate support part 111.

The substrate support part 111 supports the substrate W in a manner that allows it to rotate in the circumferential direction. The substrate support part 111 may support the substrate W in a horizontal posture.

In the following description, an XYZ orthogonal coordinate system may be used. The X direction and Y direction are parallel to an upper surface of the substrate W. The X direction and Y direction are perpendicular to each other. The Z direction is perpendicular to both the X direction and Y direction. A plan view is to view from the Z direction. The plane along the X direction and Y direction is referred to as a “XY plane”. The XY plane is, for example, a horizontal plane. The plane along the X direction and Z direction is referred to as a “XZ plane”. The plane along the Y direction and Z direction is referred to as an “YZ plane”. One direction of the X direction is +X. −X is the opposite direction of +X. The −X side is the front side. The +X side is the rear side. One direction of the Y direction is +Y. −Y is the opposite direction of +Y.

### [Fluid Supply Device] (First Embodiment)

As shown in FIG. 2 and FIG. 3, the fluid supply device 100 according to the first embodiment includes a first nozzle 11, a second nozzle 12, a first light-blocking member 21 (first Dog), a second light-blocking member 22 (second Dog), a light sensor 30, a sensing part 40, and a support part 50.

The first nozzle 11 is a tubular body that supplies the substrate W with cleaning liquid supplied from a first supply pipe (illustration omitted). The “cleaning liquid” may be either a chemical liquid or a rinse liquid. The chemical liquid may include, for example, ammonia peroxide (SC1), hydrochloric acid peroxide (SC2), sulfuric acid peroxide (SPM), sulfuric acid hydrate, hydrofluoric acid, etc. The rinse liquid includes ultra-pure water, deionized water (DIW), etc. In this embodiment, the first nozzle 11 supplies a chemical liquid (first fluid). The injection direction (supply direction) of the chemical liquid is determined by the orientation of the first nozzle 11.

The second nozzle 12 is a tubular body that supplies the substrate W with cleaning liquid supplied from a second supply pipe (illustration omitted). In this embodiment, the second nozzle 12 supplies a rinse liquid (second fluid). The injection direction (supply direction) of the rinse liquid is determined by the orientation of the second nozzle 12.

The support part 50 includes a support frame 58, a first support body 61, and a second support body 71. The support frame 58 is, for example, in the form of a plate parallel to the XZ plane. The support frame 58 extends in an up-down direction.

The first support body 61 supports the first nozzle 11. The first support body 61 includes a first mounting plate 63 and a first support plate 64. The first mounting plate 63 is parallel to the support frame 58. The first mounting plate 63 is mounted on the support frame 58. The first support plate 64 protrudes from a front end of the first mounting plate 63 towards the −Y side. The first support plate 64 has an insertion hole 64a through which the first nozzle 11 is inserted.

The second support body 71 supports the second nozzle 12. The second support body 71 includes a second mounting plate 73 and a second support plate 74. The second mounting plate 73 is parallel to the support frame 58. The second mounting plate 73 is mounted on the support frame 58. The second support plate 74 protrudes from a front end of the second mounting plate 73 towards the −Y side. The second support plate 74 has an insertion hole 74a through which the second nozzle 12 is inserted.

The first support body 61 and the second support body 71 are provided at different positions in the up-down direction (Z direction). The first support body 61 is positioned higher than the second support body 71.

The first nozzle 11 has a first holding part 62 mounted on it. The first holding part 62 is positioned on a front side of the first support plate 64 and holds the first nozzle 11. The first holding part 62 has an insertion hole 62a through which the first nozzle 11 is inserted. A connecting member 65 is mounted on a side surface of the first holding part 62 by fixtures 75, 76.

The first light-blocking member 21 includes an extension part 23 and a first light-blocking part 24. The extension part 23 includes a mounting plate 13 and an extending-out plate 14. The mounting plate 13 is in the form of a plate perpendicular to the XZ plane. The mounting plate 13 is inclined to rise towards the +X side. The mounting plate 13 is overlapped on an upper surface of the connecting member 65. The mounting plate 13 is mounted on the connecting member 65 by fixtures 77, 78.

The extending-out plate 14 includes a front panel part 15 and a back panel part 16. The extending-out plate 14 is in the form of a plate parallel to the XZ plane. The front panel part 15 is continuously arranged on a side edge of the +Y side edge of the mounting plate 13. The front panel part 15 is inclined to rise towards the +X side. The back panel part 16 extends out rearward (+X side) from a rear end of the front panel part 15.

The first light-blocking part 24 protrudes towards the −Y side from a rear end of the back panel part 16. The first light-blocking part 24 is in the form of a plate that intersects with an optical axis of the light emitted from a light-emitting part 31. The first light-blocking part 24 is, for example, in the form of a plate parallel to the YZ plane.

The first light-blocking part 24 has a first light-passing region 21a formed therein. The first light-passing region 21a is, for example, an opening (through hole) that penetrates the first light-blocking part 24 in the thickness direction. The first light-passing region 21a allows the light emitted from the light-emitting part 31 to pass through. The shape of the first light-passing region 21a is not particularly limited, but it is, for example, circular.

The first light-blocking member 21 is mounted on the first holding part 62 via the connecting member 65, and therefore is capable of being displaced in conjunction with the displacement of the first nozzle 11. The first nozzle 11 may change its posture by, for example, pivoting around a point (support point) where it is inserted into the insertion hole 64a as a fulcrum. The first light-blocking member 21 displaces integrally with the first nozzle 11 as the displacement of the first nozzle 11 is displaced.

The second nozzle 12 has a second holding part 72 mounted on it. The second holding part 72 is positioned on a front side of the second support plate 74 and holds the second nozzle 12. The second holding part 72 has an insertion hole 72a through which the second nozzle 12 is inserted.

The second holding part 72 has a connecting member 80 mounted on it. The connecting member 80 includes a mounting plate 81 and an extending-out plate 82. The mounting plate 81 is in the form of a plate parallel to the XZ plane. The mounting plate 81 is mounted on a side surface of the second holding part 72 by fixtures 85, 86.

The extending-out plate 82 includes a front panel part 83 and a back panel part 84. The extending-out plate 82 is in the form of a plate perpendicular to the XZ plane. The front panel part 83 is continuously arranged on a lower edge of the mounting plate 81. The front panel part 83 is inclined to rise towards the +X side. The back panel part 84 extends out rearward (+X side) from a rear end of the front panel part 83. A fixed member 87 is provided on an upper surface of the back panel part 84. The fixed member 87 is mounted on the back panel part 84 by a fixture 89.

The second light-blocking member 22 includes a mounting part 25, a first extending-out part 26, a second extending-out part 27, and a second light-blocking part 28. The mounting part 25 is mounted on the fixed member 87 by a fixture 88. The mounting part 25 is in the form of a plate parallel to the XZ plane. The first extending-out part 26 extends out towards the +Y side from an end of the mounting part 25 on the +X side. The second extending-out part 27 extends out downward (−Z side) from an end of the first extending-out part 26 on the +Y side. The first extending-out part 26 and the second extending-out part 27 are in the form of plates parallel to the YZ plane.

The second light-blocking part 28 extends out towards the −Y side from a lower end of the second extending-out part 27. The second light-blocking part 28 is in the form of a plate that intersects with an optical axis of the light emitted from the light-emitting part 31. The second light-blocking part 28 is, for example, in the form of a plate parallel to the YZ plane. The second light-blocking part 28 is positioned lower than the back panel part 84.

The second light-blocking part 28 has a second light-passing region 22a formed therein. The second light-passing region 22a is, for example, an opening (through hole) that penetrates the second light-blocking part 28 in the thickness direction. The second light-passing region 22a allows the light emitted from the light-emitting part 31 to pass through. The shape of the second light-passing region 22a is not particularly limited, but it is, for example, circular.

In response to the first nozzle 11 and the second nozzle 12 being at a reference position, the first light-passing region 21a and the second light-passing region 22a are positioned to overlap at least partially when viewed from the X direction.

An inner diameter of the first light-passing region 21a and an inner diameter of the second light-passing region 22a may be different, and when viewed from the X direction, one of the light-passing regions 21a, 22a may include the other. The first light-passing region 21a and the second light-passing region 22a may have the same diameter, and when viewed from the X direction, entire areas of the light-passing regions 21a, 22a may overlap.

The second light-blocking part 28 is positioned on the +X side relative to the first light-blocking part 24 of the first light-blocking member 21. The second light-blocking part 28 is, for example, parallel to the first light-blocking part 24. It is desirable that the second light-blocking part 28 is spaced apart from the first light-blocking part 24 on the +X side.

The second light-blocking member 22 is mounted on the second holding part 72 via the fixed member 87 and the connecting member 80, and therefore is capable of being displaced in conjunction with the displacement of the second nozzle 12. The second nozzle 12 may, for example, change its posture by, for example, pivoting around a point (support point) where it is inserted into the insertion hole 74a as a fulcrum. The second light-blocking member 22 displaces integrally with the second nozzle 12 in response to the displacement of the second nozzle 12.

As shown in FIG. 4, it is preferable to arrange the first light-blocking part 24 at a position where a first distance to the first nozzle 11 (the point where it passes through the insertion hole 64a of the first support plate 64) and a second distance to the second nozzle 12 (the point where it passes through the insertion hole 74a of the second support plate 74) are equivalent. “The first distance and the second distance are equivalent” means, for example, that the ratio of the first distance to the second distance is in the range of 0.8 to 1.2. For the second light-blocking part 28 as well, it is preferable that the first distance and the second distance are equivalent.

As shown in FIG. 3, the light sensor 30 includes a light-emitting part 31 and a light-receiving part 32. The light-emitting part 31 emits light for detection. The light-receiving part 32 receives light from the light-emitting part 31. The light-emitting part 31 and the light-receiving part 32 are supported by a support stand 33. The light-emitting part 31 is held in a holding groove 33a of the support stand 33. The light-receiving part 32 and the light-emitting part 31 are held in a holding groove 33b of the support stand 33. The light-emitting part 31 is, for example, a light-emitting diode (LED). The light-receiving part 32 is, for example, a phototransistor.

The light-receiving part 32 is installed at a position separated from the light-emitting part 31 on the +X side. As a result, the light from the light-emitting part 31 is emitted in a direction away from the substrate W.

It is desirable that the light sensor 30, when viewed from the X direction, is positioned in a space between the first nozzle 11 and the second nozzle 12, at least partially.

The sensing part 40 detects the displacement of at least one of the first nozzle 11 and the second nozzle 12 based on the light reception amount of the light-receiving part 32. For example, when the light reception amount is within a predetermined set range, it may be determined that the displacement of the first nozzle 11 and the second nozzle 12 is small (or there is no displacement). In the case where the light reception amount falls below a lower limit value of the set range, it may be determined that at least one of the first nozzle 11 and the second nozzle 12 has significantly displaced.

When the posture of the first nozzle 11 and the second nozzle 12 fluctuates, the position where the fluid (chemical liquid, rinse liquid, etc.) is sprayed onto the substrate W changes. The orientation of the first nozzle 11 and the second nozzle 12 may, for example, fluctuate up and down (Z direction) (refer to FIG. 4). The orientation of the first nozzle 11 and the second nozzle 12 may, for example, fluctuate left and right (Y direction) (refer to FIG. 5). When the orientation of the first nozzle 11 and the second nozzle 12 fluctuates up and down, the first light-blocking part 24 and the second light-blocking part 28 approximately displace up and down. When the orientation of the first nozzle 11 and the second nozzle 12 fluctuates left and right, the first light-blocking part 24 and the second light-blocking part 28 approximately displace left and right.

### Usage Method of the Fluid Supply Device

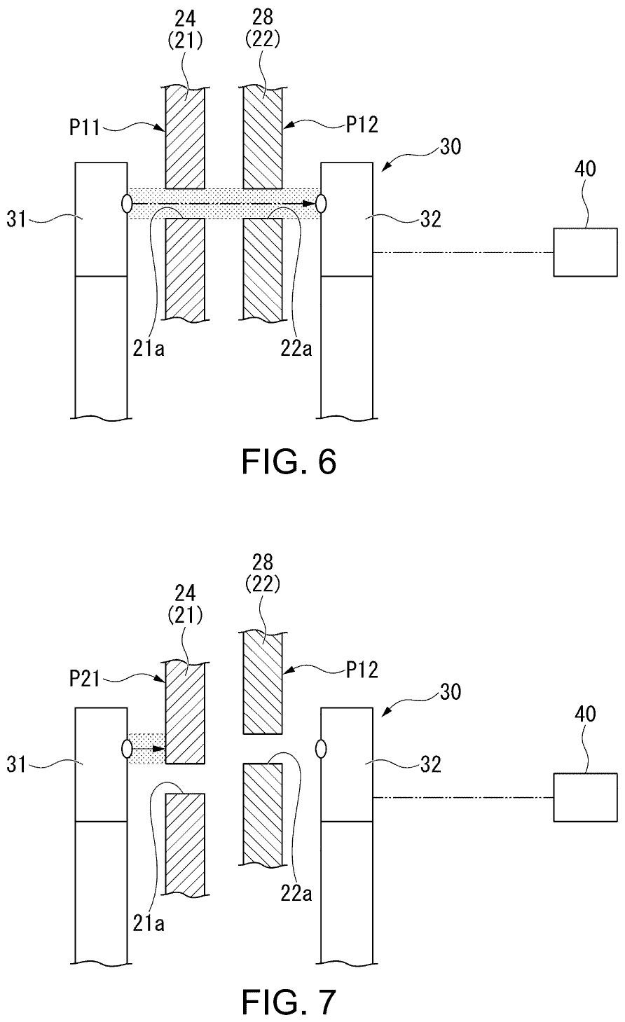

The usage method of the fluid supply device 100 will be described with reference to FIGS. 6 to 8.

As shown in FIG. 6, a first non-light-blocking position P11 is a position of the first light-blocking member 21 that does not block the light from the light-emitting part 31. As shown in FIG. 7, a first light-blocking position P21 is a position of the first light-blocking member 21 that blocks the light from the light-emitting part 31. The first light-blocking member 21 may switch between the first non-light-blocking position P11 and the first light-blocking position P21.

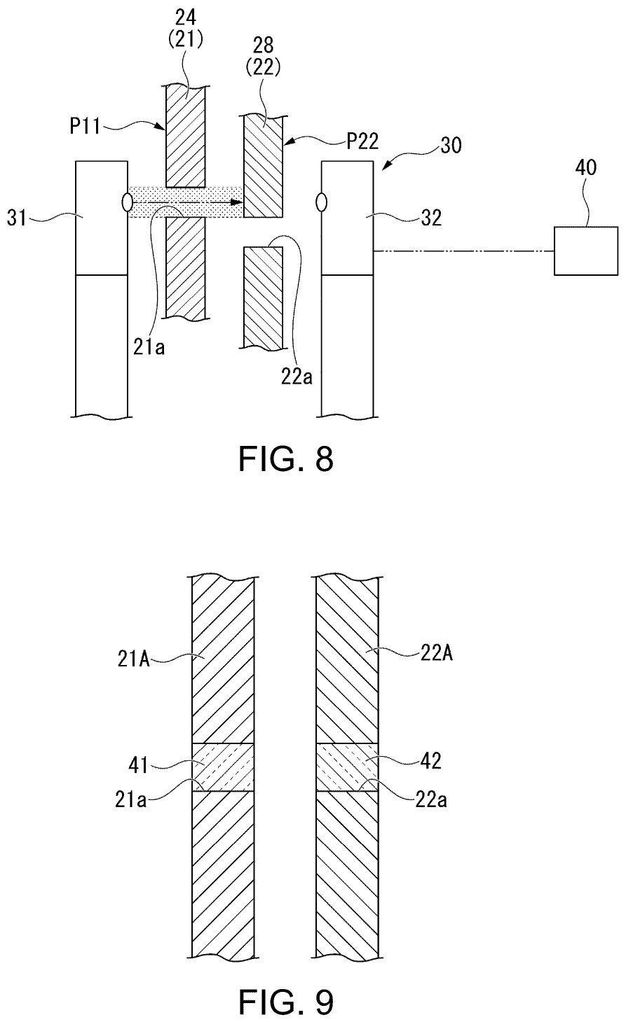

As shown in FIG. 6, a second non-light-blocking position P12 is a position of the second light-blocking member 22 that does not block the light from the light-emitting part 31. As shown in FIG. 8, a second light-blocking position P22 is a position of the second light-blocking member 22 that blocks the light from the light-emitting part 31. The second light-blocking member 22 may switch between the second non-light-blocking position P12 and the second light-blocking position P22.

As shown in FIG. 6, when the first nozzle 11 and the second nozzle 12 are at a predetermined reference position, the first light-blocking member 21 is at the first non-light-blocking position P11. The second light-blocking member 22 is at the second non-light-blocking position P12. The light from the light-emitting part 31 passes through the light-passing regions 21a, 22a and reaches the light-receiving part 32. Therefore, the light reception amount of the light-receiving part 32 is within the predetermined set range. In this case, the sensing part 40 determines that the displacement of the first nozzle 11 and the second nozzle 12 is small (or there is no displacement).

As shown in FIG. 7, when the posture of the first nozzle 11 deviates from the reference position, the position of the first light-blocking part 24 changes, and the first light-passing region 21a also displaces. In FIG. 7, the first light-blocking member 21 is at the first light-blocking position P21 that blocks the light from the light-emitting part 31. In the case where the light reception amount of the light-receiving part 32 falls below the predetermined set range, the sensing part 40 determines that the displacement of at least one of the first nozzle 11 and the second nozzle 12 is large.

As shown in FIG. 8, when the posture of the second nozzle 12 deviates from the reference position, the position of the second light-blocking part 28 changes, and the second light-passing region 22a also displaces. In FIG. 8, the second light-blocking member 22 is at the second light-blocking position P22 that blocks the light from the light-emitting part 31. In the case where the light reception amount of the light-receiving part 32 falls below the predetermined set range, the sensing part 40 determines that the displacement of at least one of the first nozzle 11 and the second nozzle 12 is large.

It is desirable that in the fluid supply device 100, the sensing part 40 is capable of detecting the displacement of the nozzles 11, 12 when the position where the fluid (chemical liquid, rinse liquid, etc.) is sprayed onto the substrate W changes from the reference position by a predetermined set value or more. The inner diameter of the light-passing regions 21a, 22a may be determined such that this displacement can be detected.

### Effects Achieved by the Fluid Supply Device of the Embodiment

In the fluid supply device 100, the first light-blocking member 21 may switch between the first non-light-blocking position P11 and the first light-blocking position P21 by displacing in conjunction with the displacement of the first nozzle 11. Therefore, when the first nozzle 11 is displaced due to a user accidentally touching the first nozzle 11, the displacement of the first nozzle 11 can be accurately detected.

In the fluid supply device 100, since the displacement of the first light-blocking member 21 can be detected by the light sensor 30, unlike detecting displacement based on images of the nozzle, there is no need for a large-scale configuration such as an imaging device, and the device configuration can be simplified. The fluid supply device 100, with its simplified device configuration, is advantageous in terms of device miniaturization and cost reduction.

In the fluid supply device 100, the second light-blocking member 22 may switch between the second non-light-blocking position P12 and the second light-blocking position P22 by displacing in conjunction with the displacement of the second nozzle 12. Therefore, when the second nozzle 12 is displaced, the displacement of the second nozzle 12 can be accurately detected. In the fluid supply device 100, since the displacement of both the first nozzle 11 and the second nozzle 12 can be detected using a single light sensor 30, space-saving is possible. Consequently, it is possible to simplify the device configuration and achieve device miniaturization.

In the fluid supply device 100, the first light-passing region 21a, which is an opening, is formed in the first light-blocking member 21 (first light-blocking part 24). Therefore, even if the first light-blocking part 24 displaces in any direction (for example, up-down and left-right directions) along the YZ plane, this displacement can be detected. Consequently, the detection accuracy of the displacement of the first nozzle 11 can be enhanced.

In the fluid supply device 100, the second light-passing region 22a, which is an opening, is formed in the second light-blocking member 22 (second light-blocking part 28). Therefore, even if the second light-blocking part 28 displaces in any direction along the YZ plane, this displacement can be detected. Consequently, the detection accuracy of the displacement of the second nozzle 12 can be enhanced.

The light sensor 30, with at least a portion positioned in the space between the first nozzle 11 and the second nozzle 12, is preferable in terms of space-saving.

The light-emitting part 31, configured to emit light in a direction away from the substrate W, can prevent the substrate W being affected by the detection light (for example, oxidation of the substrate W surface).

As shown in FIG. 4, when the distance from the first light-blocking part 24 and the distance from the second light-blocking part 28 to the first nozzle 11 and to the second nozzle 12 are equivalent, the amount of misalignment of the first light-passing region 21a due to the displacement of the first nozzle 11 can be made equivalent to the amount of misalignment of the second light-passing region 22a due to the displacement of the second nozzle 12. Therefore, both the displacement of the first nozzle 11 and the displacement of the second nozzle 12 can be accurately detected.

### Modification Example of the First Light-Blocking Member and the Second Light-Blocking Member

FIG. 9 is a schematic diagram showing a modification example of the first light-blocking member 21 and the second light-blocking member 22.

As shown in FIG. 9, a first light-blocking member 21A has a window part 41 (transparent window) made of transparent material formed in the first light-passing region 21a. A second light-blocking member 22A has a window part 42 (transparent window) made of transparent material formed in the second light-passing region 22a. The window parts 41, 42 are, for example, formed of glass, plastic, etc.

[Fluid Supply Device] (Second Embodiment)

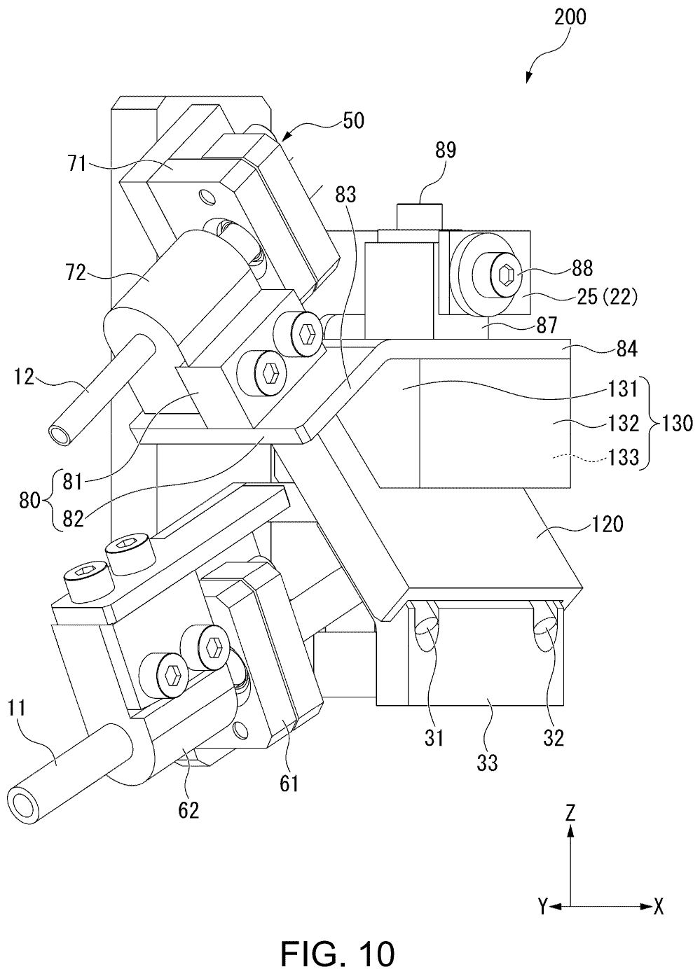

FIG. 10 is a perspective diagram of a part of a fluid supply device 200 according to the second embodiment.

The fluid supply device 200 differs from the fluid supply device 100 (refer to FIG. 2) in that it includes a first cover 120 (cover) and a second cover 130 (cover).

The first cover 120 covers the light-emitting part 31 and the light-receiving part 32. The first cover 120 is mounted on an outer surface of the support stand 33.

The second cover 130 includes a front panel 131, a side panel 132, and a back panel 133. The second cover 130 covers at least a part of the light-blocking members 21, 22 (specifically, the light-blocking parts 24, 28) (refer to FIG. 2). The front panel 131, the side panel 132, and support stand 33 hang down from a lower surface of the back panel part 84 of the connecting member 80.

The front panel 131 is parallel to the YZ plane. The front panel 131 is positioned forward (−X side) compared to the first light-blocking part 24. The front panel 131 is sized to encompass the light-passing regions 21a, 22a when viewed from the X direction. The side panel 132 extends out towards the +X side from an end of the front panel 131 on the −Y side. The side panel 132 is parallel to the XZ plane. The side panel 132 is positioned on an outer side (−Y side) with respect to the light-blocking parts 24, 28 (refer to FIG. 2). The side panel 132 encompasses the light-passing regions 21a, 22a when viewed from the Y direction. The back panel 133 extends out towards the +Y side from an end of the side panel 132 on the +X side. The back panel 133 is parallel to the YZ plane. The back panel 133 is positioned rearward (+X side) compared to the second light-blocking part 28. The back panel 133 encompasses the light-passing regions 21a, 22a when viewed from the X direction.

The fluid supply device 200 includes the second cover 130 that covers at least a part of the light-blocking members 21, 22 (specifically, the light-blocking parts 24, 28). As a result, it is possible to suppress false detection caused by fluid droplets (for example, cleaning liquid) adhering to the light-passing regions 21a, 22a.

The technical scope of the disclosure is not limited to the embodiments, and various modifications may be made within the scope that does not deviate from the spirit of the disclosure.

In the fluid supply device, while it is preferable that the “fluid” being supplied is a liquid, the fluid is not limited to liquids. For example, the fluid may be a gas. The fluid may be a gas-liquid mixture. The fluid may be a solid-liquid mixture containing both liquid and solid.

The fluid supply device 100 shown in FIG. 2 has two nozzles, but the number of nozzles is not particularly limited. The number of nozzles may be one or multiple (any number of two or more). For example, the fluid supply device may include multiple nozzles for supplying chemical liquid and one nozzle for supplying rinse liquid.

The light-passing regions 21a, 22a of the first light-blocking member 21 and the second light-blocking member 22 shown in FIG. 3 are openings, but the light-passing regions may be recesses formed on a periphery of the first light-blocking member and the second light-blocking member.

The first light-blocking position P21 may be a position of the first light-blocking member 21 that blocks at least a part of the light from the light-emitting part 31. The second light-blocking position P22 may be a position of the second light-blocking member 22 that blocks at least a part of the light from the light-emitting part 31.

The light sensor 30 is configured to detect that at least one of the first light-blocking member 21 and the second light-blocking member 22 is in the light-blocking position. However, the light sensor may be configured to detect that at least one of the first light-blocking member and the second light-blocking member is in a non-light-blocking position.

Furthermore, within the scope that does not deviate from the spirit of the disclosure, it is possible to appropriately replace the components in the embodiments with known components, and the embodiments and modification examples may be appropriately combined.

What is claimed is:

1. A fluid supply device, comprising:
a first nozzle that supplies a first fluid toward an object;
a light sensor that comprises a light-emitting part that emits light for detection, and a light-receiving part that receives the light;
a first light-blocking member capable of being positioned in a first non-light-blocking position that does not block the light and a first light-blocking position that blocks the light; and
a sensing part that detects displacement of the first nozzle based on a light reception amount of the light-receiving part,
wherein the first light-blocking member is capable of switching between the first light-blocking position and the first non-light-blocking position by displacing in conjunction with the displacement of the first nozzle.

2. The fluid supply device according to claim 1, further comprising:
a second nozzle that supplies a second fluid toward the object; and
a second light-blocking member capable of being positioned in a second non-light-blocking position that does not block the light and a second light-blocking position that blocks the light,
wherein the second light-blocking member is capable of switching between the second light-blocking position and the second non-light-blocking position by displacing in conjunction with a displacement of the second nozzle.

3. The fluid supply device according to claim 1, wherein a first light-passing region through which the light passes is formed in the first light-blocking member.

4. The fluid supply device according to claim 3, wherein the first light-passing region is an opening or a transparent window.

5. The fluid supply device according to claim 2, wherein a second light-passing region through which the light passes is formed in the second light-blocking member.

6. The fluid supply device according to claim 5, wherein the second light-passing region is an opening or a transparent window.

7. The fluid supply device according to claim 2,
wherein at least a part of the light sensor is positioned in a space between the first nozzle and the second nozzle.

8. The fluid supply device according to claim 1, wherein the light-emitting part emits the light in a direction away from the object.

9. The fluid supply device according to claim 1, further comprising a cover that covers at least a part of the first light-blocking member.
